(19) United States
(12) Patent Application Publication
(10) Pub. No.: US 2024/0081055 A1
(43) Pub. Date: Mar. 7, 2024

(54) SEMICONDUCTOR STRUCTURE AND FABRICATING METHOD OF THE SAME

(71) Applicant: UNITED MICROELECTRONICS CORP., Hsin-Chu City (TW)

(72) Inventors: Hsuan-Kai Wang, Tainan City (TW); Chao-Sheng Cheng, Taichung City (TW); Chi-Cheng Huang, Kaohsiung City (TW)

(73) Assignee: UNITED MICROELECTRONICS CORP., Hsin-Chu City (TW)

(21) Appl. No.: 17/953,336

(22) Filed: Sep. 27, 2022

(30) Foreign Application Priority Data
Sep. 1, 2022 (CN) 202211061087.4

(51) Int. Cl. H01L 27/11531; H01L 21/3105; H01L 21/8234; H01L 27/11521; H01L 27/11548

(52) U.S. Cl. CPC H01L 27/11531; H01L 21/31053; H01L 21/823437; H01L 27/11521; H01L 27/11548

(57) ABSTRACT

A semiconductor structure includes a substrate. The substrate is divided into a first element region, a second element region and a boundary region. The boundary region is disposed between the first element region and a second element region. A first mask structure covers the first element region. A second mask structure is disposed in the second element region. A logic gate structure is disposed within the second element region.

### BACKGROUND OF THE INVENTION

### 1. Field of the Invention

The present invention relates to a semiconductor structure and a fabricating method of the same, and more particular to a method which combines fabricating steps performed in different device regions and a semiconductor structure formed by the method.

### 2. Description of the Prior Art

Currently, in the semiconductive field, in order to reduce the size of a chip, various semiconductor devices, such as logic transistors, high voltage transistors or non-volatile memory structures, are formed on a single die or a substrate to increase the integration.

However, increase of the integration will seriously affect the fabricating processes of logic transistors, high voltage transistors or non-volatile memory structures. Logic transistors, high-voltage transistors, and non-volatile memory structures respectively require different fabricating processes. For example, logic transistors are generally fabricated by using a metal-oxide-semiconductor process, while high-voltage transistors need steps for forming thicker gate oxides. As for the non-volatile memory structure, steps such as making a floating gate and a control gate are required.

In order to integrate the above-mentioned devices on the same substrate, a manufacturing process which is compatible for all devices is in need.

### SUMMARY OF THE INVENTION

According to a preferred embodiment of the present invention, a semiconductor structure includes a substrate, wherein the substrate is divided into a first element region, a second element region and a boundary region, and the boundary region is disposed between the first element region and the second element region. A first mask structure covers the first element region. A second mask structure is disposed in the boundary region. A logic gate structure is disposed within the second element region.

According to another preferred embodiment of the present invention, a fabricating method of a semiconductor structure includes providing a substrate, wherein the substrate is divided into a first element region, a second element region and a boundary region, and the boundary region is disposed between the first element region and a second element region. Next, a mask is formed to cover the first element region, the boundary region and the second element region. Then, the mask is patterned to form a trench within the boundary region and the mask which is within the second element region is entirely removed to segment the mask into a first mask and a second mask, wherein the first mask is within the first element region and the second mask is within the boundary region. After that, a gate structure stack is formed to cover the first mask, to fill in the trench and cover the second mask and the second element region. After that, an anti-reflection coating is formed to entirely cover a top surface of the gate structure stack. Subseciently, the gate structure stack is patterned to form a logic gate structure within the second element region. Finally, the anti-reflection coating is removed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 depict a semiconductor structure according to a preferred embodiment of the present invention, wherein:

FIG. 1 depicts a substrate with a memory device structure and a polysilicon layer thereon;

FIG. 2 is a fabricating stage in continuous of FIG. 1;

FIG. 3 is a fabricating stage in continuous of FIG. 2;

FIG. 4 shows a top view of a semiconductor structure in the stage of FIG. 3;

FIG. 5 is a fabricating stage in continuous of FIG. 3;

FIG. 6 is a fabricating stage in continuous of FIG. 5; and

FIG. 7 is a fabricating stage in continuous of FIG. 6.

FIG. 8 shows a fabricating stage in continuous of FIG. 2 according to another preferred embodiment of the present invention.

FIG. 9 shows a semiconductor structure according to another preferred embodiment of the present invention.

FIG. 10 shows a fabricating stage according to an example of the present invention.

### DETAILED DESCRIPTION

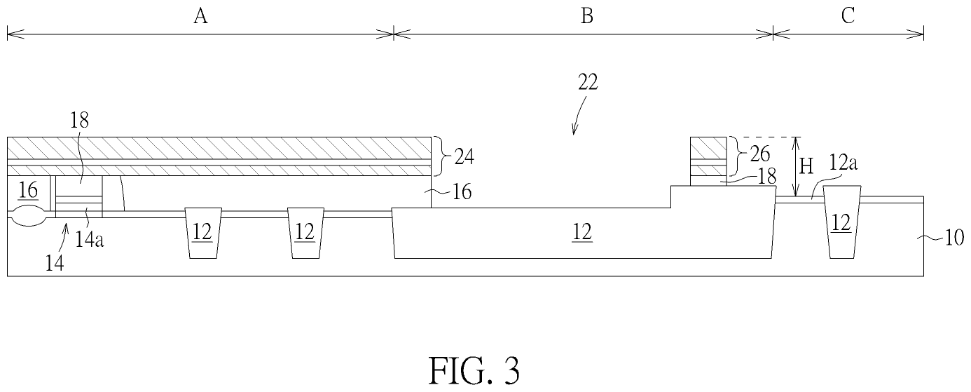

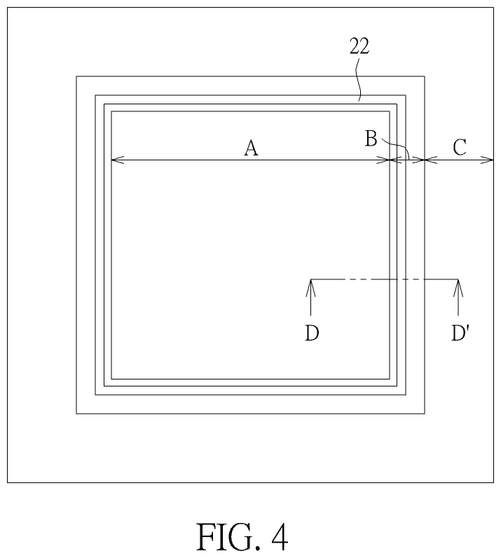

FIG. 1 to FIG. 7 depict a semiconductor structure according to a preferred embodiment of the present invention, wherein FIG. 3 depicts a sectional view taken along line DD′ in FIG. 4.

As shown in FIG. 1, a substrate 10 is provided. The substrate 10 is divided into a first element region A, a second element region C and a boundary region B. The boundary region B is disposed between the first element region A and the second element region C. The first element region A and the second element region C respectively include semiconductor devices with different structures. Therefore, the fabricating process of semiconductor devices within the first element region A and the second element region C is different. For example, the first element region A may include a high voltage transistor region or a memory cell region, and the second element region C may include a logic circuit region or a core circuit region. The high voltage transistor region is used for high voltage transistors to dispose. The memory cell region is used for flashes to dispose. The logic circuit region is used for input/output transistors or core transistors to dispose. Because the device to be formed in the first element region A is different from the device to be formed in the second element region C, the fabricating process performed to the first element region A will influence the device in the second element region C. For example, the fabricating process for forming the memory cell within the first element region A will shift the location of the gate within the second element region C. The fabricating process of the present invention can solve the influence to the devices in second element region C causing by the fabricating process in the first element region A.

Please refer to FIG. 1. Shallow trench isolations 12 are respectively embedded within the first element region A, the second element region C and the boundary region B of the substrate 10. A memory device structure 14 is disposed within the first element region A. Part of the shallow trench isolation 12 within the boundary region B is removed to make the shallow trench isolation 12 within the boundary region B has a stair profile. A polysilicon layer 16 covers the first element region A and the boundary region B. A silicon nitride layer 18 covers the boundary region B and the second element region C. The memory device structure 14 includes a floating gate 14a and a silicon nitride layer 18.

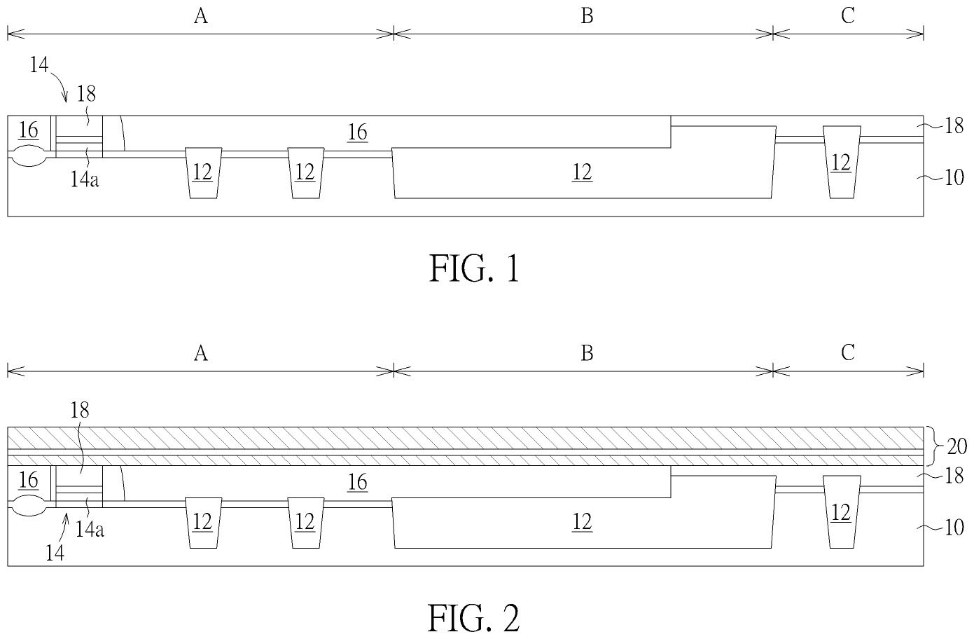

As shown in FIG. 2, a mask 20 is formed to cover the first element region A, the boundary region B and the second element region C. The mask 20 contacts the polysilicon layer 16, the memory device structure 14 and the silicon nitride layer 18. The mask 20 preferably includes silicon oxide-silicon nitride-silicon oxide stack. As shown in FIG. 3 and FIG. 4, the mask 20, the polysilicon layer 16 and the silicon nitride layer 18 are patterned to form a trench 22 within the boundary region B, and the mask 20 within the second element region C and the silicon nitride layer 18 within the second element region C are entirely removed. The trench 22 segments the mask 20 into a first mask 24 and a second mask 26, and an end of the polysilicon layer 16 within the boundary region B is removed to make the second mask 26 not contact the polysilicon layer 16. The first mask 24 is within the first element region A and the second mask 26 is within the boundary region B. In details, the first mask 24 contacts the polysilicon layer 16. The second mask 26 contacts the silicon nitride layer 18. The trench 22 preferably surrounds the first element region A. Furthermore, a step height H is formed between a top surface of the second mask 26 and a top surface of the silicon oxide layer 12a within the second element region C.

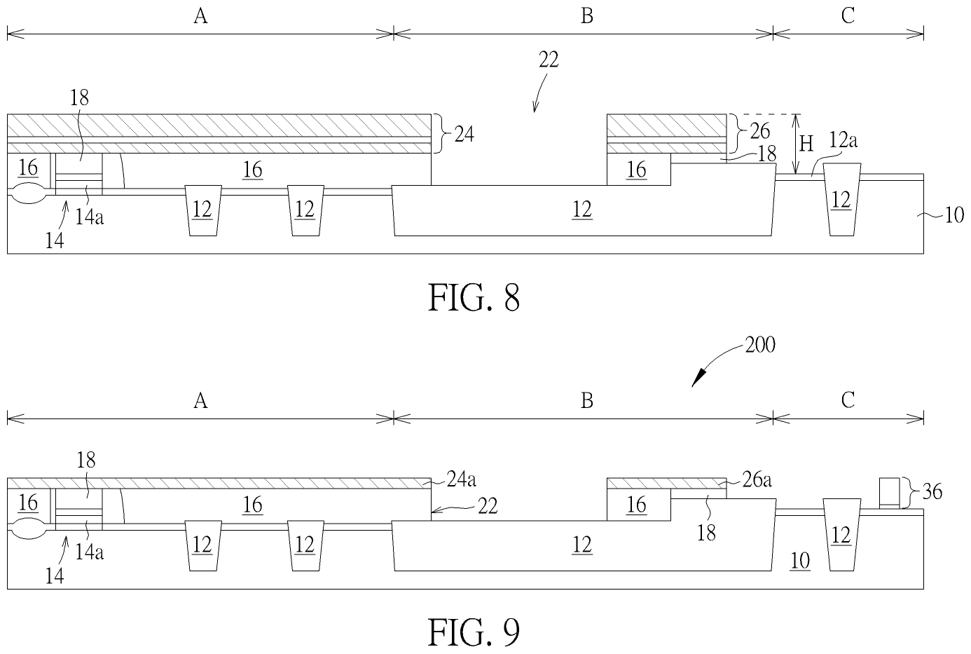

According to another preferred embodiment of the present invention, as shown in FIG. 8, the trench 22 segments the mask 20 and the polysilicon layer 16. The trench 22 segments the mask 20 into a first mask 24 and a second mask 26. After segmenting, the remaining polysilicon layer 16 is respectively within the first element region A and the boundary region B. The polysilicon layer 16 within the boundary region B is under the second mask 26. The polysilicon layer 16 within the first element region A is under the first mask 24. The difference between FIG. 8 and FIG. 3 is that in FIG. 8, there is polysilicon layer 16 under the second mask 26 and the polysilicon layer 16 contacts the second mask 26. On the contrary, there is no polysilicon layer 16 under the second mask 26 in FIG. 3.

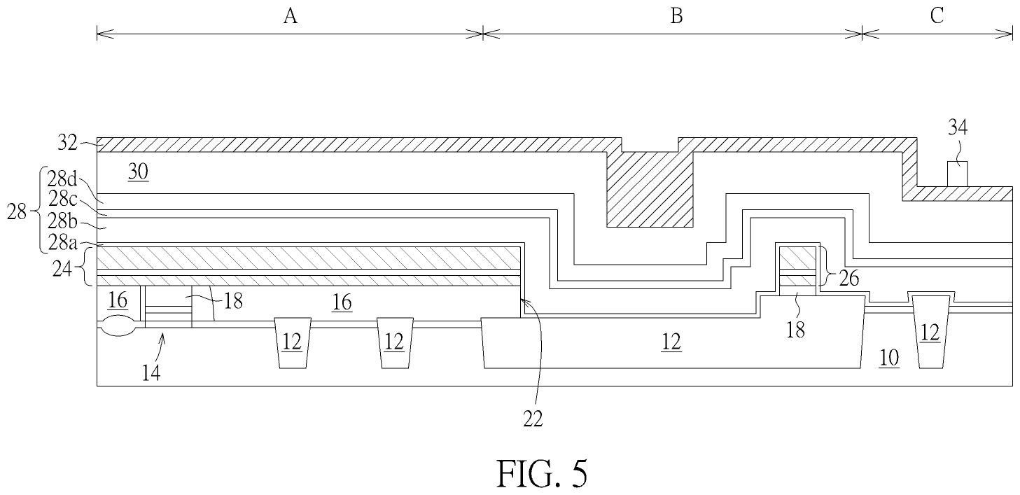

As shown in FIG. 5, in continuous of FIG. 3, a gate structure stack 28 is formed to cover the first mask 24, filling in the trench 22, covering the second mask 26 and the second element region C. The gate structure stack 28 includes a high-k dielectric material layer 28a, a polysilicon layer 28b, a silicon nitride mask 28c and a silicon oxide mask 28d from bottom to top. Then, an advanced patterning film (APF) 30 and a bottom anti-reflective coating (BARC) 32 are formed in sequence to entirely cover the top surface of the gate structure stack 28. In details, the APF 30 and the BARC 32 cover the first mask 24, fill in the trench 22, and cover the second mask 26 and the second element region C. Then, a photoresist 34 is formed within the second element region C.

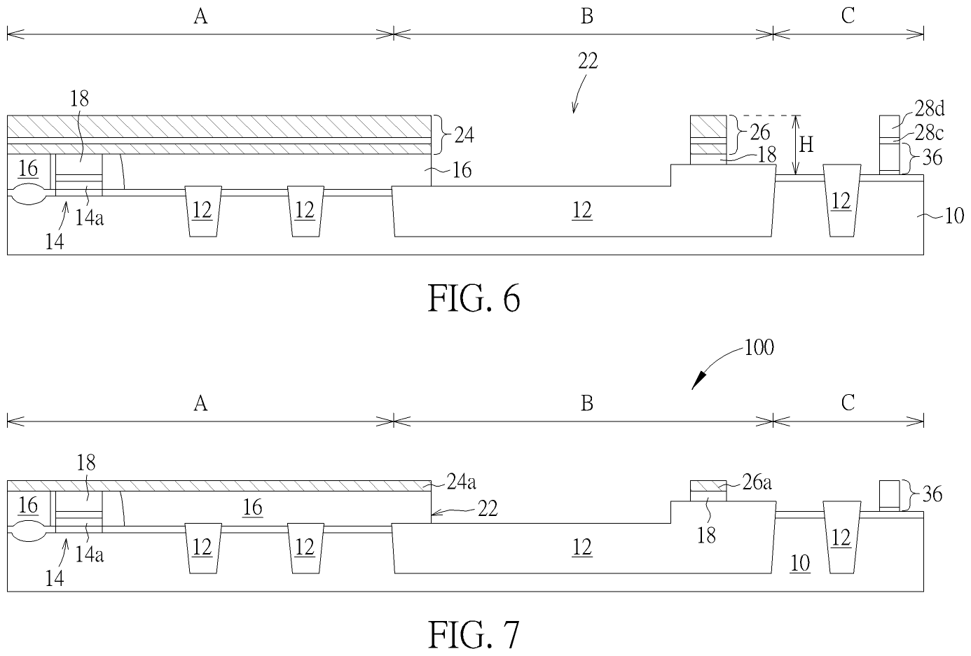

As shown in FIG. 6, the gate structure stack 28 is patterned to form at least one logic gate structure 36 within the second element region C. Later, the BARC 32 and the APF 30 are removed. As shown in FIG. 7, after removing the silicon oxide which is the topmost layer of the first mask 24 and the second mask 26, and the silicon nitride which is at the middle of the first mask 24 and the second mask 26, the first mask 24 becomes a first mask structure 24a, and the second mask 26 becomes a second mask structure 26a. More specifically speaking, the first mask structure 24a and the second mask structure 26a respectively contain only one silicon oxide layer. Now, a semiconductor structure of the present invention is completed.

As shown in FIG. 7, according to another preferred embodiment of the present invention, a semiconductor structure 100 includes a substrate 10. The substrate 10 is divided into a first element region A, a second element region C and a boundary region B, and the boundary region B is disposed between the first element region A and the second element region C. The first element region A includes a high voltage transistor region or a memory cell region, and the second element region C includes a logic circuit region. A shallow trench isolation 12 is optionally disposed within the substrate 10 at the boundary region B. A first mask structure 24a covers the first element region A. A second mask structure 26a is disposed in the boundary region B. The second mask structure 26a can optionally be disposed on the shallow trench isolation 12. The first mask structure 24a and the second mask structure 26 are both made of insulating material. In this embodiment, both of the first mask structure 24a and the second mask structure 26 respectively include one silicon oxide layer.

A logic gate structure 36 is disposed within the second element region C. A polysilicon layer 16 covers the first element region A. The polysilicon layer 16 is disposed between the first mask structure 24a and the substrate 10. The second mask structure 26a does not contact the polysilicon layer 16. However, the position of the polysilicon layer 16 can be altered based on different requirements. As shown in FIG. 9, according to another preferred embodiment of the present invention, the polysilicon layer 16 of the semiconductor structure 200 covers the first element region A and the boundary region B. The polysilicon layer 16 within the first element region A is disposed between the first mask structure 24a and the substrate 10, and the polysilicon layer 16 within the boundary region B is disposed under the second mask structure 26a and contacts the second mask structure 26a.

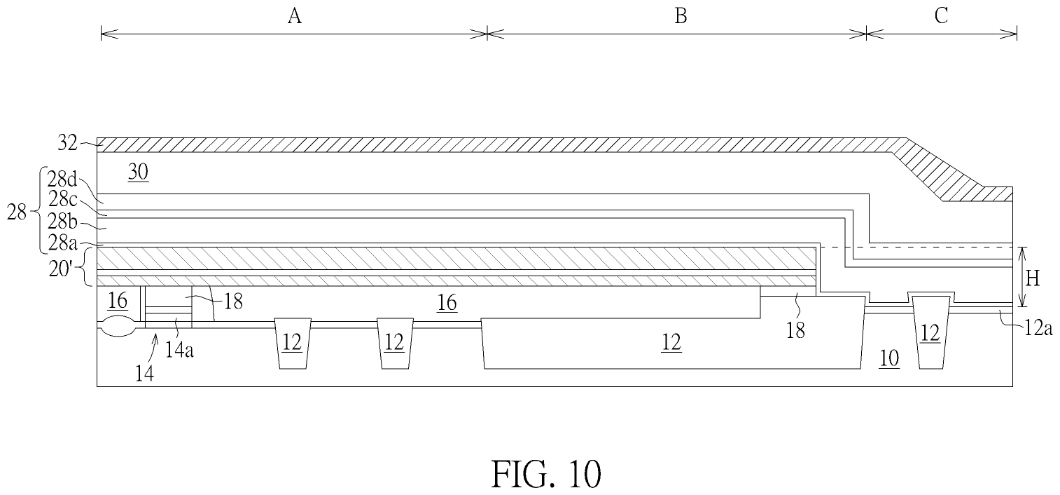

FIG. 10 depicts fabricating method of a semiconductor structure according to an example of the present invention, wherein elements which are substantially the same as those in the embodiment of FIG. 3 and FIG. 5 are denoted by the same reference numerals; an accompanying explanation is therefore omitted.

Please refer to FIG. 3 and FIG. 10. There is no trench 22 in FIG. 10. However, similar to steps in FIG. 3, steps in FIG. 10 also remove the silicon nitride layer 18 and the mask 20 (please refer to FIG. 2 for the positions of the silicon nitride layer 18 and the mask 20) within the second element region C. Therefore, in the steps of FIG. 10, a step height H is also formed between the top surface of the mask 20′ and the top surface of the silicon oxide 12a within the second element region C. Please refer to FIG. 5 and FIG. 10. Because fluidity of the APF 30 and the BARC 32 is high, they will accumulate at locations where is relatively low. As shown in FIG. 10, because of the step height H within the second element region C, which means that the top surface of the silicon oxide 12a is relatively low, the thickness of the APF 30 and the thickness of the BARC 32 within the second element region C are greater than the thickness of the APF 30 and the thickness of the BARC 32 within the first element region A. Different thicknesses cause a shift of the logic gate structure while defining the location of the logic gate structure. As shown in FIG. 5, because there is the trench 22 within the boundary region C, part of the APF 30 and part of the BARC 32 will flow into the trench 22. In this way, the thickness of the APF 30 and the thickness of the BARC 32 within the boundary region C become smaller, and the positions of the logic gate structure will be accurate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate, wherein the substrate is divided into a first element region, a second element region and a boundary region, and the boundary region is disposed between the first element region and the second element region;
a first mask structure covering the first element region;
a second mask structure disposed in the boundary region; and
a logic gate structure disposed within the second element region.

2. The semiconductor structure of claim 1, further comprising: a polysilicon layer covering the first element region, wherein the polysilicon layer is disposed between the first mask structure and the substrate, and the second mask structure does not contact the polysilicon layer.

3. The semiconductor structure of claim 1, further comprising: a polysilicon layer covering the first element region and the boundary region, wherein the polysilicon layer within the first element region is disposed between the first mask structure and the substrate, and the polysilicon layer within the boundary region is disposed under the second mask structure and contacts the second mask structure.

4. The semiconductor structure of claim 1, wherein the first mask structure only comprises a silicon oxide layer, and the second mask structure only comprises the silicon oxide layer.

5. The semiconductor structure of claim 1, wherein the first element region comprises a high voltage transistor region or a memory cell region, and the second element region comprises a logic circuit region.

6. The semiconductor structure of claim 1, wherein the first mask structure is made of insulating material.

7. The semiconductor structure of claim 1, further comprising a shallow trench isolation disposed within the substrate at the boundary region.

8. The semiconductor structure of claim 7, wherein the second mask structure is disposed on the shallow trench isolation.

9. A fabricating method of a semiconductor structure, comprising:
providing a substrate, wherein the substrate is divided into a first element region, a second element region and a boundary region, and the boundary region is disposed between the first element region and a second element region;
forming a mask covering the first element region, the boundary region and the second element region;
patterning the mask to form a trench within the boundary region and entirely removing the mask which is within the second element region to segment the mask into a first mask and a second mask, wherein the first mask is within the first element region and the second mask is within the boundary region;
forming a gate structure stack covering the first mask, filling the trench and covering the second mask and the second element region;
forming an anti-reflection coating entirely covering a top surface of the gate structure stack;
patterning the gate structure stack to form a logic gate structure within the second element region; and
removing the anti-reflection coating.

10. The fabricating method of a semiconductor structure of claim 9, further comprising:
before forming the mask, forming a polysilicon layer covering the first element region and the boundary region.

11. The fabricating method of a semiconductor structure of claim 10, wherein the trench segments the mask and the polysilicon layer, the polysilicon layer after patterning is respectively at the first element region and the boundary region, the polysilicon layer within the boundary region is disposed under the second mask and contacts the second mask.

12. The fabricating method of a semiconductor structure of claim 10, wherein the trench segments the mask and removes an end of the polysilicon layer which is within the boundary region to keep the second mask from contacting the polysilicon layer.

13. The fabricating method of a semiconductor structure of claim 9, wherein the mask comprises silicon oxide-silicon nitride-silicon oxide stack.

14. The fabricating method of a semiconductor structure of claim 9, wherein the mask is made of insulating material.

15. The fabricating method of a semiconductor structure of claim 9, wherein the trench surrounds the first element region.

16. The fabricating method of a semiconductor structure of claim 9, further comprising a shallow trench isolation disposed within the substrate at the boundary region.

17. The fabricating method of a semiconductor structure of claim 16, wherein the second mask is disposed on the shallow trench isolation.

18. The fabricating method of a semiconductor structure of claim 9, wherein the first element region comprises a high voltage transistor region or a memory cell region, and the second element region comprises a logic circuit region.
